(19) United States
(12) Patent Application Publication
(10) Pub. No.: US 2026/0320260 A1
(43) Pub. Date: Oct. 15, 2026

(54) EVALUATION SYSTEM FOR VEHICULAR SENSING SYSTEM BASED ON SYNTHETIC SENSOR DATA

(71) Applicant: Magna Electronics Inc., Auburn Hills, MI (US)

(72) Inventors: Sanjay Narayana Murthy, Karnataka (IN); Lakshmi Narasimha Prathap Laddagiri, Karnataka (IN)

(21) Appl. No.: 19/641,769

(22) Filed: Apr. 8, 2026

Related U.S. Application Data
(60) Provisional application No. 63/785,786, filed on Apr. 9, 2025.

(51) Int. Cl. G06F 30/27; G01M 17/007

(52) U.S. Cl. CPC G06F 30/27; G01M 17/007

(57) ABSTRACT

A method includes generating a synthetic dataset simulating sensor data of the vehicle by rendering a simulated environment from a viewpoint of at least one modeled virtual sensor. The modeled virtual sensor is configured according to physical and optical properties of a corresponding physical sensor of the vehicle. The method includes providing the synthetic dataset and associated ground truth information as input to the perception stack. The method includes receiving, from the perception stack, an output based on processing of the synthetic dataset. The method includes determining a performance metric of the perception stack by comparing the output against the associated ground truth information.

### CROSS REFERENCE TO RELATED APPLICATION

The present application claims the filing benefits of U.S. provisional application Ser. No. 63/785,786, filed Apr. 9, 2025, which is hereby incorporated herein by reference in its entirety.

### TECHINCAL FIELD

The present invention relates generally to evaluating a vehicle vision system for a vehicle and, more particularly, to evaluating a vehicle vision system that utilizes one or more cameras at a vehicle.

### BACKGROUND

Use of imaging sensors in vehicle imaging systems is common and known. Examples of such known systems are described in U.S. Pat. Nos. 5,949,331; 5,670,935 and/or 5,550,677, which are hereby incorporated herein by reference in their entireties.

### SUMMARY

A method for evaluating a perception stack of a vehicle includes generating a synthetic dataset simulating sensor data of the vehicle by rendering a simulated environment from a viewpoint of at least one modeled virtual sensor. The modeled virtual sensor is configured according to physical and optical properties of a corresponding physical sensor of the vehicle. The method includes providing the synthetic dataset and associated ground truth information as input to the perception stack. The method includes receiving, from the perception stack, an output based on processing of the synthetic dataset. The method includes determining a performance metric of the perception stack by comparing the output against the associated ground truth information.

These and other objects, advantages, purposes and features of the present invention will become apparent upon review of the following specification in conjunction with the drawings.

### BRIEF DESCRIPTION OF THE DRAWINGS

FIG. 1 is a plan view of a vehicle with a vision system that incorporates cameras; and

FIG. 2 is a flowchart for evaluating the vision system of FIG. 1.

### DETAILED DESCRIPTION

Perception stacks, which typically include software and algorithms and/or models for processing sensor data, enable autonomous systems to understand and interpret their environment. Different vendors provide various perception stacks, each optimized for specific hardware setups and applications. Directly testing these perception stacks on target hardware with real-world data is not only expensive but also time-consuming, including extensive field testing, data collection, and hardware deployment.

The evaluation of perception stacks in autonomous systems via real-world data collection and hardware testing has limitations. One limitation of current benchmarking and/or evaluation approaches is a lack of a controlled and repeatable testing framework that allows for consistent performance comparisons across different perception stacks. The high cost of deploying real-world tests further restricts innovation and optimization in development of perception algorithms. Additionally, testing perception algorithms and/or models on physical hardware limits flexibility and imposes constraints on iterative improvements. Thus, evaluating perception stacks is a complex and time-consuming process in developing autonomous systems, including across various hardware platforms and real-world scenarios.

A vehicle vision system and/or driver or driving assist system and/or object detection system and/or alert system operates to capture images exterior of the vehicle and may process the captured image data to display images and to detect objects at or near the vehicle and in the predicted path of the vehicle, such as to assist a driver of the vehicle in maneuvering the vehicle in a rearward direction. The vision system includes an image processor or image processing system or processor or processing system (i.e., data processing hardware) and memory hardware that is operable to receive image data from one or more cameras and provide an output to a display device for displaying images representative of the captured image data. Optionally, the vision system may provide a display, such as a rearview display or a top down or bird's eye or surround view display or the like.

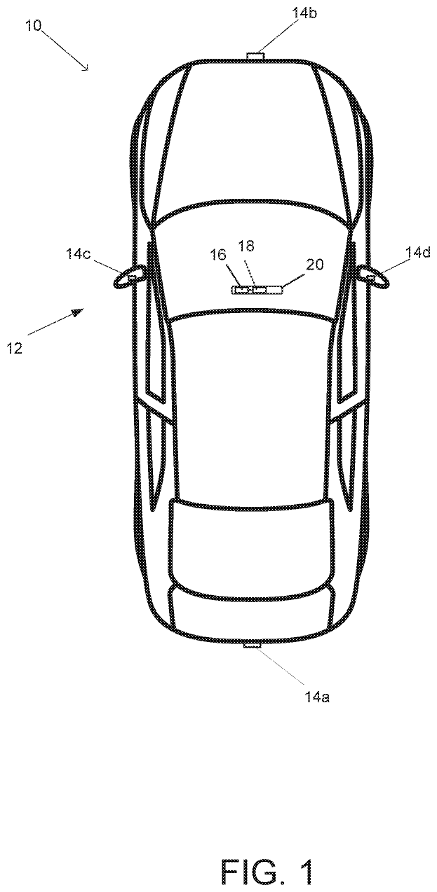

Referring now to the drawings and the illustrative embodiments depicted therein, a vehicle 10 includes an imaging system or vision system 12 that includes at least one exterior viewing imaging sensor or camera, such as a rear backup camera or rearward viewing imaging sensor or camera 14a (and the system may optionally include multiple exterior viewing imaging sensors or cameras, such as a forward viewing camera 14b at the front (or at the windshield) of the vehicle, and a sideward/rearward viewing camera 14c, 14d at respective sides of the vehicle), which captures images exterior of the vehicle, with the camera having a lens for focusing images at or onto an imaging array or imaging plane or imager of the camera (FIG. 1). Optionally, a forward viewing camera may be disposed at the windshield of the vehicle and view through the windshield and forward of the vehicle, such as for a machine vision system (such as for traffic sign recognition, headlamp control, pedestrian detection, collision avoidance, lane marker detection and/or the like). The vision system 12 includes a control or electronic control unit (ECU) 18 having electronic circuitry and associated software, with the electronic circuitry including a data processor or image processor that is operable to process image data captured by the camera or cameras, whereby the ECU may detect or determine presence of objects or the like and/or the system provide displayed images at a display device 16 for viewing by the driver of the vehicle (although shown in FIG. 1 as being part of or incorporated in or at an interior rearview mirror assembly 20 of the vehicle, the control and/or the display device may be disposed elsewhere at or in the vehicle). The data transfer or signal communication from the camera to the ECU may comprise any suitable data or communication link, such as a vehicle network bus or the like of the equipped vehicle.

Implementations herein provide a systematic benchmarking, testing, and/or evaluation framework for evaluating perception stacks used in autonomous systems, such as self-driving vehicles and/or semi-autonomous vehicles and/or vehicular driving assist systems. In some examples, the evaluation framework may be a method for evaluating perception stacks used in autonomous systems. In other examples, the evaluation framework may be a system. The framework leverages high-fidelity synthetic datasets, generated through detailed sensor modeling and scenario simulation, to assess perception stack performance across various metrics.

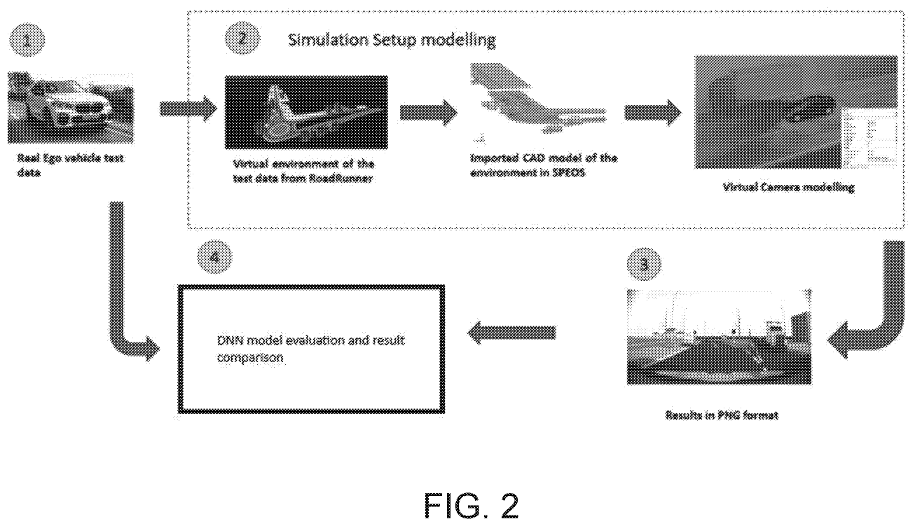

Testing involving real-world data acquisition (as represented in step 1 of FIG. 2) may include extensive field testing, sensor calibration, and, often, manual annotation. This process may be resource-intensive and include hardware limitations, storage demands, annotation complexity, and difficulty capturing rare or hazardous scenarios (e.g., extreme weather, accidents). These limitations underscore the utility of synthetic data as a complementary or alternative approach for comprehensive benchmarking. That is, there is a need for perception stack evaluation and/or comprehensive benchmarking that uses synthetic data and/or synthetic datasets instead of or in addition to real-world data. In some implementations of the evaluation framework described herein, certain real-world data may still be acquired or utilized, for instance, to serve as a basis for comparison or validation of results obtained using the synthetic datasets (as discussed further below), thereby helping to quantify and bridge the reality gap (i.e., the difference between synthetic data and real-world data and/or the difference between simulation and reality), rather than serving as the primary or sole evaluation dataset.

The evaluation framework includes generating synthetic data tailored for perception stack evaluation and using this data in a structured evaluation process. An example workflow or flowchart, as illustrated in FIG. 2, may involve steps such as sensor modeling, synthetic data generation, and Deep Neural Network (DNN) model evaluation (representing components of the perception stack). The workflow may include simulation setup modeling, producing results of the performance of the perception stack in the simulation (e.g., in a . PNG file format), and performing DNN model evaluation and results comparison. The simulation setup modeling may include modeling a virtual environment of the synthetic test data, importing a CAD model of the virtual environment, and virtual camera modeling of a virtual vehicle equipped with the perception stack. Results comparison may include comparing performance of the perception stack based on the synthetic dataset versus performance of the perception stack based on collected real-world test data. Optionally, the workflow includes collecting real-world test data (i.e., real ego vehicle test data).

A component of the evaluation framework may involve generating a synthetic dataset that simulates sensor data captured by a vehicle. For example, the sensor data may simulate sensor data captured by one or more sensors of a vehicle in various driving conditions, where the sensors may include radar sensors, image sensors (e.g., cameras), lidar sensors, or ultrasonic sensors. This process of generating the synthetic dataset includes modeling the sensors, such as camera sensors, radar sensors, lidar, etc., based on their physical and/or optical properties. This modeling may increase realism of the synthetic data and reduce the gap between simulation and reality.

Properties considered during camera modeling may include optics parameters such as horizontal field of view (HFOV), vertical field of view (VFOV), focal length, imager distance, F-number, transmittance characteristics (e.g., via a transmittance file), lens distortion characteristics (e.g., via a distortions file), etc. Additional properties may include sensor parameters such as pixel count and arrangement (resolution), sensor dimensions, color mode (e.g., RGB, monochrome), gamma correction, white balance mode, output format details (e.g., PNG bits), etc. In some examples, the synthetic dataset may include modeling the camera sensor based on properties such as HFOV, VFOV, resolution, focal length, F-number, transmittance characteristics, or lens distortion characteristics. In other examples, the synthetic dataset may include modeling the camera sensor based on properties such as resolution, sensor dimensions, color mode, gamma correction, white noise balance mode, or output format details. Additional examples of properties or parameters include acquisition parameters such as integration time and lag time, sensitivity characteristics according to color mode and defined wavelength range, sampling rate, and/or axis definition (i.e., position and orientation of the sensor, such as position and orientation of the sensor with respect to the vehicle). Optionally, the synthetic dataset may include modeling the camera sensor based on properties such as integration time and lag time, sensitivity characteristics according to color mode and defined wavelength range, sampling rate, or axis definition.

Simulation tools and environments may be employed for the process of generating the synthetic dataset. For instance, environment modeling may be performed using tools like MATLAB RoadRunner for feature modeling (e.g., road types like highway, urban, sub-urban; lane properties like width, curve, elevation; and environmental objects) and asset modeling (e.g., road layouts, vehicles, pedestrians, buildings, signals, posts, vegetation, etc.). The modeled environment CAD data (e.g., in .stl format, .xodr format, GeoJSON format) may then be imported into physics-based simulation and rendering tools, such as ANSYS Speos or potentially game engines like Unreal Engine (compatible with tools like CARLA, LGSVL, AimSim, dSPACE, AVx, etc.).

Within the simulation tool (e.g., ANSYS Speos), material properties are assigned to objects using material libraries (e.g., assigning properties for glass, metal, asphalt, water, fog, paint, plastic, etc.). Lighting sources (e.g., environmental, uniform, natural light simulating time of day) and environmental factors (e.g., simulating weather conditions like fog, rain, snow, or clear skies) may be configured.

The framework utilizes simulated scenarios, potentially based on standardized test protocols like the New Car Assessment Program (NCAP), including EURO NCAP standards. These scenarios simulate real-world conditions, such as various driving environments, weather conditions, and object interactions, providing a structured basis for generating diverse and relevant synthetic data. Example real-world conditions may include simulating pedestrian crossings, vehicle following or braking, lane changes, and interactions at intersections under different environmental conditions. For example, the real-world driving conditions may include simulating following of another vehicle ahead of the vehicle equipped with the perception stack or braking responsive to the other vehicle.

Synthetic sensor data may be generated using the modeled camera sensor(s), radar sensors, lidar sensors, ultrasonic sensors, or other sensors within these simulated scenarios. This process typically involves rendering the scene from the modeled camera's viewpoint and/or the sensors' position and orientation with respect to the vehicle and applying the defined optical and sensor properties to generate synthetic images or sensor readings that mimic real-world sensor output. Variations in weather, lighting, and road conditions may be systematically introduced to enhance data diversity and realism, facilitating robustness testing.

The generated synthetic dataset, along with ground truth information associated with the generated synthetic dataset (e.g., precise locations and classes of objects, lane markings, segmentation masks inherent to the simulation), is provided as input to the perception stack under evaluation. The perception stack processes the synthetic sensor data. Additionally or alternatively, the perception stack may process the associated ground truth information, such as for comparison of performance of the perception stack based on the synthetic sensor data with performance of the perception stack based on the ground truth information.

The perception stack may include various modules, such as DNN models for tasks like object detection, semantic segmentation, and lane detection. Examples of such models include, but are not limited to, YOLOv4, YOLOP (which notably leverages a multi-task learning strategy to handle object detection, semantic segmentation, and lane detection concurrently within a single network), Mobilenet SSD, or other relevant algorithms designed for perception tasks in autonomous systems. The choice of model or specific perception stack configuration may depend on the target application and performance requirements (e.g., balancing accuracy and real-time processing needs).

The framework receives an output from the perception stack based on the perception stack's processing of the synthetic dataset. This output may include detected object bounding boxes with class labels and confidence scores, pixel-level segmentation maps, detected lane lines, etc. In some examples, the output may correspond to the task performed by the DNN model of the perception stack. The performance of the perception stack may be determined by comparing the perception stack's output against the known ground truth associated with the synthetic dataset. For example, performance is evaluated based on predefined metrics.

Relevant metrics may include accuracy, such as precision, recall, F1-score, and/or mean average precision (mAP) for object detection. Other metrics may include intersection over union (loU) for segmentation, latency (i.e., the time taken by the perception stack to process the input data and generate an output, which is a valuable metric for real-time applications), and robustness (i.e., performance consistency across various simulated conditions, such as different weather, lighting, and other scenarios). Additional examples of metrics may include computational costs (i.e., resource utilization, such as central processing unit (CPU) and/or graphics processing unit (GPU) load, or memory usage, measured during execution on target or simulated hardware platforms, etc.). That is, wherein evaluating the performance of the perception stack may include determining mAP, loU, latency, robustness, accuracy, and/or computational cost of the perception stack.

Comprehensive reports may be generated by the framework detailing the test results, including statistical performance metrics and hardware performance metrics. The comprehensive reports may allow for comparison between different perception stacks or different versions of the same perception stack. To further validate the synthetic benchmarking approach and/or framework and bridge the reality gap, the metrics or performance metrics derived from the synthetic dataset (e.g., accuracy, latency) for a given perception stack may be compared against performance metrics obtained from evaluating the same perception stack using the corresponding real-world test data, when available. Stated differently, the evaluation framework may compare the determined performance of the perception stack based on the synthetic dataset with a corresponding performance determined using real-world test data.

The framework may facilitate iterative development of the perception stack. If the evaluation using synthetic data reveals performance deficiencies of the perception stack (e.g., low confidence scores for detected objects, poor accuracy on certain scenarios), a portion of the generated synthetic dataset may be used to retrain or fine-tune components of the perception stack, such as the DNN models (e.g., adjusting hyperparameters, using low learning rates, applying data augmentation techniques suited for synthetic data). The retrained and/or fine-tuned perception stack may then be re-evaluated using another portion of the synthetic dataset. Additionally or alternatively, the retrained and/or fine-tuned perception stack may then be re-evaluated using the entire synthetic dataset and/or another synthetic dataset different from the synthetic dataset used to retrain or fine-tune the perception stack.

The evaluation may extend to the entire perception pipeline (i.e., end-to-end testing) within the simulated environment, measuring overall system accuracy and latency of the perception stack to ensure real-time processing standards, metrics, and/or requirements are met. Detailed error analysis of misclassifications or detection failures of the perception stack on the synthetic data may help identify specific weaknesses in the perception stack for targeted improvements.

This synthetic data-driven evaluation framework offers several advantages. It may significantly reduce the cost and time associated with traditional testing methods by minimizing the need for extensive physical setups and real-world data collection. Stated differently, by using synthetic data, the evaluation framework may reduce cost and time associated with design, development, testing, or validation of a perception stack for a vehicle and/or a vehicular system compared to evaluation frameworks that rely on real-world data. It provides a controlled, repeatable, and scalable environment for benchmarking, allowing for consistent comparisons across different perception stacks or development iterations. The framework enables comprehensive testing under a wide range of simulated conditions, including potentially hazardous or rare scenarios (such as emergency braking events, sudden pedestrian intrusions, or complex interactions in adverse weather) that are difficult, dangerous, or impractical to replicate safely and/or repeatedly in the real world. This capability allows for thorough validation of perception stack robustness in critical situations, directly contributing to the development and deployment of safer autonomous systems. The evaluation framework allows for thorough validation of perception stack performance in various driving scenarios, improving safety of autonomous vehicles, semi-autonomous vehicles, and/or vehicular driving assist systems.

Furthermore, by abstracting away from specific hardware during initial evaluation phases (evaluation may be done based on the synthetic data itself, potentially on simulation platforms), it offers flexibility and may accelerate development cycles. For example, the evaluation framework may allow for performing initial perception stack evaluation phases without considering specific configurations of sensing hardware of the vehicle. The evaluation framework may result in the development and deployment of more reliable and robust perception technologies for autonomous systems and/or vehicular driving assist systems. Moreover, the framework's operations, including large-scale simulation execution, data management, and distributed evaluations, may be implemented utilizing cloud computing resources for enhanced scalability and accessibility, and/or edge computing resources for performance assessments closer to target hardware deployment environments, thus improving computational efficiency and adaptability across diverse applications. For example, the evaluation framework may improve computational efficiency and adaptability of perception stack evaluation across different vehicle architectures, sensing systems, and/or sensing hardware.

While challenges related to the “reality gap” exist (i.e., ensuring synthetic data accurately reflects real-world complexities and that perception models evaluated or trained using synthetic data do not overfit to the synthetic domain, which could impede real-world performance), careful and detailed modeling of sensors, environments, and scenarios, as described herein, may reduce this gap, enabling use of synthetic data for perception stack evaluation and even potential retraining. That is, the evaluation framework may reduce the reality gap between perception stack evaluation using synthetic data and perception stack evaluation using real-world data. Accordingly, the methods and systems described herein facilitate the evaluation and improvement of autonomous perception technologies, contributing to their safer and more reliable real-world deployment. The methods and systems described herein may improve evaluation and development of vehicular perception technology and may improve safety and reliability of vehicular sensing systems and/or vehicular driving assist systems.

The camera or sensor may comprise any suitable camera or sensor. Optionally, the camera may comprise a “smart camera” that includes the imaging sensor array and associated circuitry and image processing circuitry and electrical connectors and the like as part of a camera module, such as by utilizing aspects of the vision systems described in U.S. Pat. No. 10,099,614 and/or 10,071,687, which are hereby incorporated herein by reference in their entireties.

The system includes an image processor operable to process image data captured by the camera or cameras, such as for detecting objects or other vehicles or pedestrians or the like in the field of view of one or more of the cameras. For example, the image processor may comprise an image processing chip selected from the EYEQ family of image processing chips available from Mobileye Vision Technologies Ltd. of Jerusalem, Israel, and may include object detection software (such as the types described in U.S. Pat. Nos. 7,855,755; 7,720,580 and/or 7,038,577, which are hereby incorporated herein by reference in their entireties), and may analyze image data to detect vehicles and/or other objects. Responsive to such image processing, and when an object or other vehicle is detected, the system may generate an alert to the driver of the vehicle and/or may generate an overlay at the displayed image to highlight or enhance display of the detected object or vehicle, in order to enhance the driver's awareness of the detected object or vehicle or hazardous condition during a driving maneuver of the equipped vehicle.

The vehicle may include any type of sensor or sensors, such as imaging sensors or radar sensors or lidar sensors or ultrasonic sensors or the like. The imaging sensor of the camera may capture image data for image processing and may comprise, for example, a two dimensional array of a plurality of photosensor elements arranged in at least 640 columns and 480 rows (at least a 640×480 imaging array, such as a megapixel imaging array or the like), with a lens focusing images onto the imaging array. The photosensor array may comprise a plurality of photosensor elements arranged in a photosensor array having rows and columns. The imaging array may comprise a CMOS imaging array having at least 300,000 photosensor elements or pixels, preferably at least 500,000 photosensor elements or pixels and more preferably at least one million photosensor elements or at least two million photosensor elements or pixels or at least three million photosensor elements or pixels or at least five million photosensor elements or pixels arranged in rows and columns. The imaging array may be sensitive to near-infrared light. The imaging array may capture color image data, such as via spectral filtering at the array, such as via an RGB (red, green and blue) filter or via a red/red complement filter or such as via an RCC (red, clear, clear) filter or the like. The logic and control circuit of the imaging sensor may function in any known manner, and the image processing and algorithmic processing may comprise any suitable means for processing the images and/or image data.

For example, the vision system and/or processing and/or camera and/or circuitry may utilize aspects described in U.S. Pat. Nos. 9,233,641; 9,146,898; 9,174,574; 9,090,234; 9,077,098; 8,818,042; 8,886,401; 9,077,962; 9,068,390; 9,140,789; 9,092,986; 9,205,776; 8,917,169; 8,694,224; 7,005,974; 5,760,962; 5,877,897; 5,796,094; 5,949,331; 6,222,447; 6,302,545; 6,396,397; 6,498,620; 6,523,964; 6,611,202; 6,201,642; 6,690,268; 6,717,610; 6,757,109; 6,802,617; 6,806,452; 6,822,563; 6,891,563; 6,946,978; 7,859,565; 5,550,677; 5,670,935; 6,636,258; 7,145,519; 7,161,616; 7,230,640; 7,248,283; 7,295,229; 7,301,466; 7,592,928; 7,881,496; 7,720,580; 7,038,577; 6,882,287; 5,929,786 and/or 5,786,772, and/or U.S. Publication Nos. US-2014-0340510; US-2014-0313339; US-2014-0347486; US-2014-0320658; US-2014-0336876; US-2014-0307095; US-2014-0327774; US-2014-0327772; US-2014-0320636; US-2014-0293057; US-2014-0309884; US-2014-0226012; US-2014-0293042; US-2014-0218535; US-2014-0218535; US-2014-0247354; US-2014-0247355; US-2014-0247352; US-2014-0232869; US-2014-0211009; US-2014-0160276; US-2014-0168437; US-2014-0168415; US-2014-0160291; US-2014-0152825; US-2014-0139676; US-2014-0138140; US-2014-0104426; US-2014-0098229; US-2014-0085472; US-2014-0067206; US-2014-0049646; US-2014-0052340; US-2014-0025240; US-2014-0028852; US-2014-005907; US-2013-0314503; US-2013-0298866; US-2013-0222593; US-2013-0300869; US-2013-0278769; US-2013-0258077; US-2013-0258077; US-2013-0242099; US-2013-0215271; US-2013-0141578 and/or US-2013-0002873, which are all hereby incorporated herein by reference in their entireties. The system may communicate with other communication systems via any suitable means, such as by utilizing aspects of the systems described in U.S. Pat. Nos. 10,071,687; 9,900,490; 9,126,525 and/or 9,036,026, which are hereby incorporated herein by reference in their entireties.

Changes and modifications in the specifically described embodiments can be carried out without departing from the principles of the invention, which is intended to be limited only by the scope of the appended claims, as interpreted according to the principles of patent law including the doctrine of equivalents.

1. A method for evaluating a perception stack of a vehicle, the method comprising:
generating a synthetic dataset simulating sensor data of the vehicle by rendering a simulated environment from a viewpoint of at least one modeled virtual sensor, wherein the modeled virtual sensor is configured according to physical and optical properties of a corresponding physical sensor of the vehicle;
providing the synthetic dataset and associated ground truth information as input to the perception stack;
receiving, from the perception stack, an output based on processing of the synthetic dataset; and
determining a performance metric of the perception stack by comparing the output against the associated ground truth information.

2. The method of claim 1, wherein determining the performance metric comprises determining at least one of:
an accuracy;
a latency;
a robustness;
a mean average precision;
an intersection over union; or
a computational cost of the perception stack.

3. The method of claim 1, wherein generating the synthetic dataset further comprises simulating at least one standardized vehicle assessment protocol scenario, and wherein rendering the simulated environment comprises rendering the at least one standardized vehicle assessment protocol scenario.

4. The method of claim 1, wherein the physical and optical properties comprise at least one of:
a horizontal field of view;
a vertical field of view;
a resolution;
a focal length;
an F-number;
transmittance characteristics; or
lens distortion characteristics.

5. The method of claim 3, wherein the at least one standardized vehicle assessment protocol scenario simulates at least one condition selected from:
a specific driving environment;
a weather condition;
a pedestrian crossing;
a vehicle following event; or
an intersection interaction.

6. The method of claim 1, further comprising retraining the perception stack using at least a portion of the generated synthetic dataset based on the determined performance metric.

7. The method of claim 1, wherein the perception stack comprises at least one deep neural network (DNN) model configured for at least one task comprising:
object detection;
semantic segmentation; or
lane detection.

8. The method of claim 7, wherein the output received from the perception stack comprises at least one of:
detected object bounding boxes;
pixel-level segmentation maps; or
detected lane lines corresponding to the at least one task.

9. The method of claim 1, wherein rendering the simulated environment comprises assigning material properties from a material library to objects within the simulated environment to generate physics-based synthetic sensor data.

10. The method of claim 1, further comprising comparing the determined performance metric of the perception stack based on the synthetic dataset with a corresponding performance metric determined using real-world test data.

11. A system for evaluating a perception stack of a vehicle, the system comprising:
memory hardware storing instructions that, when executed on data processing hardware in communication with the memory hardware, cause the data processing hardware to perform operations comprising:
generating a synthetic dataset simulating sensor data of the vehicle by rendering a simulated environment from a viewpoint of at least one modeled virtual sensor, wherein the modeled virtual sensor is configured according to physical and optical properties of a corresponding physical sensor of the vehicle;
providing the synthetic dataset and associated ground truth information as input to the perception stack;
receiving, from the perception stack, an output based on processing of the synthetic dataset; and
determining a performance metric of the perception stack by comparing the output against the associated ground truth information.

12. The system of claim 11, wherein to determine the performance metric, the instructions further cause the system to determine at least one of:
an accuracy;
a latency;
a robustness;
a mean average precision;
an intersection over union; or
a computational cost of the perception stack.

13. The system of claim 11, wherein:
generating the synthetic dataset comprises simulating at least one standardized vehicle assessment protocol scenario; and
rendering the simulated environment comprises rendering the at least one standardized vehicle assessment protocol scenario.

14. The system of claim 11, wherein the physical and optical properties comprise at least one of:
a horizontal field of view;
a vertical field of view;
a resolution;
a focal length;
an F-number;
transmittance characteristics; or
lens distortion characteristics.

15. The system of claim 13, wherein the at least one standardized vehicle assessment protocol scenario simulates at least one condition selected from:
a specific driving environment;
a weather condition;
a pedestrian crossing;
a vehicle following event; or
an intersection interaction.

16. The system of claim 11, wherein the operations further comprise retraining the perception stack using at least a portion of the generated synthetic dataset based on the determined performance metric.

17. The system of claim 11, wherein the perception stack comprises at least one deep neural network (DNN) model configured for at least one task comprising:
object detection;
semantic segmentation; or

18. The system of claim 17, wherein the output received from the perception stack comprises at least one of:
detected object bounding boxes;
pixel-level segmentation maps; or
detected lane lines corresponding to the at least one task.

19. The system of claim 11, wherein rendering the simulated environment comprises assigning material properties from a material library to objects within the simulated environment to generate physics-based synthetic sensor data.

20. The system of claim 11, wherein the operations further comprise comparing the determined performance metric of the perception stack based on the synthetic dataset with a corresponding performance metric determined using real-world test data.
